(19) United States
(12) Patent Application Publication
(10) Pub. No.: US 2025/0251462 A1
(43) Pub. Date: Aug. 7, 2025

(54) ABNORMAL CELL DETECTION IN ENERGY STORAGE SYTEMS AND BALANCING METHOD FOR SUCH ENERGY STORAGE SYSTEMS

(71) Applicant: Skeleton Technologies GmbH, GROßRÖHRSDORF (DE)

(72) Inventor: Tarmo TRUMMAL, GROßRÖHRSDORF (DE)

(21) Appl. No.: 19/040,547

(22) Filed: Jan. 29, 2025

(30) Foreign Application Priority Data
Feb. 1, 2024 (DE) 10 2024 102 852.1

(51) Int. Cl. G01R 31/392; G01R 31/367; G01R 31/3842; G01R 31/396; G01R 31/64; H02J 7/00

(52) U.S. Cl. CPC G01R 31/392; G01R 31/367; G01R 31/3842; G01R 31/396; G01R 31/64; H02J 7/0014; H02J 7/007182; H02J 2207/50

(57) ABSTRACT

A method for detecting an abnormal cell in an energy storage system with a plurality of energy storage cells connected in series and operatively coupled to a storage management system. The storage management system performs the following steps: a) for each energy storage cell, obtaining cell data indicative of a cell leakage current level of the respective energy storage cell, the cell data at least including balancing-on-time; b) for each energy storage cell, determining a cell leakage level based on the balancing-on-time (BOT); and for each energy storage cell, determining the energy storage cell to be an abnormal cell, when the cell leakage level resulting from step b) exceeds a predetermined threshold.

### CROSS-REFERENCES TO RELATED APPLICATIONS

This application claims the benefit of German Patent Application Number 10 2024 102 852.1 filed on Feb. 1, 2024, the entire disclosure of which is incorporated herein by way of reference.

### FIELD OF THE INVENTION

The invention relates to methods for detecting abnormal energy storage cells and balancing energy storage systems having such abnormal energy storage cells.

### BACKGROUND OF THE INVENTION

Energy storage systems that include multiple energy storage cells typically require some sort of management of cell voltages. This may have different causes, such as variations in manufacturing or—over time—degradation of the cells depending on environmental conditions or usage conditions, for example.

Energy storage cells as described herein may be classified into three varieties: batteries, capacitors and ultracapacitors (sometimes also called supercapacitors).

The term “battery” as used herein is an energy storage cell that stores electrical energy exclusively by electrochemical redox reaction. This typically includes primary batteries that can only be discharged. However, as used herein, the term “battery” exclusively means secondary battery, i.e., a battery that may be charged and discharged.

The term “capacitor” as used herein is an energy storage cell that stores electrical energy electrostatically.

The term “ultracapacitor” as used herein is a special kind of capacitor and may be further distinguished into a double-layer capacitor (DLC) that stores energy electrostatically using a Helmholtz double layer, a pseudocapacitor that stores electrical energy electrochemically by Faradaic electron charge-transfer such as intercalation or electrosorption, or a hybrid capacitor that uses both mechanisms of the DLC and the pseudocapacitor.

Different methods for detecting abnormally behaving cells and solutions to mitigate said behavior have been developed. Reference is made to the following approaches:

US 2015/0 044 527 A1 discloses a battery management circuit that senses individual voltage of each battery cell for detecting a failing cell. The battery management circuit prevents a failing cell from contributing to an output voltage of the battery.

U.S. Pat. Nos. 11,133,133 B2, 10,649,040 B2 and 11,124,087 B2 disclose measures for identifying abnormal cells based on leakage current.

EP 3 800 762 A1 discloses a control unit that is capable of detecting an abnormal cell in a battery module and of controlling cell balancing.

U.S. Pat. No. 7,683,575 B2 discloses a method for identifying and selectively disconnecting a faulty battery cell within a battery pack of several battery cells.

U.S. Pat. No. 9,097,774 B2 discloses a method for identifying a faulty cell based on the amount the cell requires balancing.

U.S. Pat. No. 9,866,043 B2 discloses an apparatus that disconnects a faulty cell by activating a sacrificial component by providing a current through the faulty cell.

US 2021/0 281 084 A1 discloses a method for performing a balancing operation based on a difference of voltages.

U.S. Pat. No. 8,796,993 B2 discloses a method for balancing based on a Coulomb threshold level.

U.S. Pat. No. 5,227,259 A discloses an apparatus for locating and electrically isolating failed cells in a network of cells within a battery.

U.S. Pat. No. 5,894,212 A discloses a battery cell protection system that isolates a faulty cell.

U.S. Pat. No. 10,317,477 B2 discloses an inspection method for a secondary battery in off-line mode.

### SUMMARY OF THE INVENTION

It is an object of the invention to provide improved energy storage management measures, that are preferably particularly suited for ultracapacitors.

The object may be achieved by the subject-matter of one or more embodiments described herein.

The invention provides a method for detecting an abnormal cell in an energy storage system, the energy storage system comprising a plurality of energy storage cells that are connected in series and operatively coupled to a storage management system, the storage management system performing the steps of:
a) for each energy storage cell, obtaining cell data that are indicative of a cell leakage current level of the respective energy storage cell, the cell data at least including balancing-on-time (BOT);
b) for each energy storage cell, determining a cell leakage level based on the balancing-on-time (BOT); and
c) for each energy storage cell, determining the energy storage cell to be an abnormal cell, if the result of step b) exceeds a predetermined threshold and optionally meets at least one condition during a current detection period, and storing the respective energy storage cell as being an abnormal cell for the current detection period.

Preferably, step b) includes determining an imbalance change among the energy storage cells between the current detection period and a directly preceding detection period, wherein a first condition is met, if the imbalance change is smaller than a predetermined threshold.

Preferably, step b) includes determining a difference between a minimum BOT and a maximum BOT among the energy storage cells, wherein a second condition is met, if this difference is greater or equal to a predetermined threshold.

Preferably, step c) includes that the energy storage cell is determined to be an abnormal cell, if the result of step b) exceeds the predetermined threshold and each condition is met.

Preferably, step c) includes determining an abnormal cell to be a normal cell, if the result of step b) does not exceed the predetermined threshold or at least one condition is not met during the current detection period.

Preferably, steps a) to c) are carried out in a loop.

The invention provides a preparatory part of a balancing method for an energy storage system, the energy storage system comprising at least one energy storage module, each energy storage module having a plurality of energy storage cells, the method comprising a storage management system performing the steps of:
a) determining a normal cell voltage increase for normal energy storage cells due to allowing abnormal cells to drop, and determining a maximum allowed imbalance for abnormal cells;
b) determining a minimum and a maximum cell voltage of all energy storage cells excluding the abnormal cells;
c) determining a minimum and a maximum algorithm voltage for further processing in a balancing method by subtracting the normal cell voltage increase for normal energy storage cells due to allowing abnormal cells to drop from the minimum and maximum cell voltages obtained in step b).

The maximum allowed imbalance can be a predetermined value or can be calculated using the cell voltages and cell leakage characteristic. The leakage characteristic can be measured or modeled using methods well-known in the art.

The invention provides a balancing method for an energy storage system, the energy storage system comprising at least one energy storage module, each energy storage module having a plurality of energy storage cells, the method comprising a storage management system to perform the steps of:
a) detecting the presence of at least one abnormal cell;
b) determining a normal cell voltage increase due to allowing each abnormal cell to drop in voltage;
c) for each energy storage cell, setting the respective energy storage cell to a balance-on-state or a balance-off-state depending on the result of step b), wherein in the balance-on-state the operating voltage of the energy storage cell is decreased.

Preferably, in step a) the presence of each abnormal cell is detected by a preferred method.

Preferably, step b) includes carrying out a preferred preparatory part of the balancing method to determine the normal cell voltage increase due to allowing each abnormal cell to drop in voltage.

Preferably, step b) includes determining a cell balancing coefficient, and step c) includes setting the respective energy storage cell to the balancing-on-state, if the cell balancing coefficient exceeds a predetermined threshold, and setting the respective energy storage cell to the balancing-off-state otherwise.

Preferably, step b) includes determining a maximum allowed imbalance for abnormal cells and determining an abnormal delta voltage, wherein the abnormal delta voltage is indicative of a difference between the total decrease of abnormal cell voltages, and the allowed limit of total increase of normal cell voltages, and step c) includes setting the respective energy storage cell to the balancing-on-state, if the maximum allowed imbalance is smaller than or equal to zero or if the abnormal delta voltage is greater than or equal to zero, and to the balancing-off-state otherwise.

Preferably, the method is carried out in a loop.

The invention provides a storage management system comprising means to perform the disclosed methods.

The invention provides an energy storage module comprising a plurality of energy storage cells and a storage management system that is configured as a module controller.

The invention provides an energy storage rack comprising a plurality of energy storage modules, each including a plurality of energy storage cells, and a storage management system that is preferably formed by multiple module controllers or a rack controller.

The invention provides an energy storage system comprising at least one energy storage rack.

The invention provides a machine-readable data storage that includes instructions, that upon execution by a computer or microcontroller cause the computer or microcontroller to perform at least one step of a disclosed method, or that upon synthesizing in a programmable circuit chip, configure the circuit chip to perform at least one step of a disclosed method.

In some embodiments a method for detecting an abnormal cell in an energy storage system, the energy storage system comprising a plurality of energy storage cells that are connected in series and operatively coupled to a storage management system, includes the storage management system performing the steps of:
a) for each energy storage cell, obtaining cell data that are indicative of a cell leakage current level of the respective energy storage cell, the cell data at least including balancing-on-time;
b) for each energy storage cell, determining a cell leakage level based on the balancing-on-time (BOT); and
c) for each energy storage cell, determining the energy storage cell to be an abnormal cell, if the cell leakage level resulting from step b) exceeds a predetermined threshold.

Preferably, the method comprises a step d) of measuring an imbalance change and/or calculating a difference between a minimum and a maximum BOT, and performing step c) only, if in addition to the cell leakage level exceeding the predetermined threshold, the imbalance change is smaller than a second predetermined threshold and/or the difference between the minimum and maximum BOT is greater than or equal to a third predetermined threshold.

In some embodiments a preparatory part of a balancing method for an energy storage system, the energy storage system comprising at least one energy storage module, each energy storage module having a plurality of energy storage cells, includes a storage management system performing the steps of:
a) determining a normal cell voltage increase for normal energy storage cells due to allowing abnormal cells to drop, and determining a maximum change of the cell voltages;
b) determining a minimum and a maximum cell voltage of all energy storage cells excluding the abnormal cells;
c) determining a minimum and a maximum cell voltage of all energy storage cells including the abnormal cells in order to determine the minimum and maximum algorithm voltage for further processing.

In some embodiments a main part of a balancing method for an energy storage system, the energy storage system comprising at least one energy storage module, each energy storage module having a plurality of energy storage cells, includes a storage management system to perform the steps of:
a) obtaining input parameters for determining cell balancing coefficients;
b) performing a weighted balancing method with a set of cell balancing coefficients, wherein the set of cell balancing coefficients includes cell balancing coefficients each based on a cell voltage of the respective cell and the input parameters of step a).

Preferably, in step a) the input parameters are obtained by performing the preferred preparatory part of the balancing method. Preferably, the input parameters are selected from a group consisting of a minimum and a maximum algorithm voltage, and a minimum and a maximum module voltage of the energy storage module.

Preferably, in step b) each cell balancing coefficient is additionally based on a normal cell voltage increase for normal energy storage cells due to allowing abnormal cells to drop.

Preferably, in step b) each cell balancing coefficient is additionally based on an allowed system voltage imbalance.

In some embodiments a storage management system comprises means to perform the preferred methods.

In some embodiments an energy storage module comprises a plurality of energy storage cells and a preferred storage management system that is configured as a module controller.

In some embodiments an energy storage rack comprises a plurality of energy storage modules, each including a plurality of energy storage cells, and a preferred storage management system that is preferably formed by multiple module controllers or a rack controller.

In some embodiments an energy storage system comprises at least one preferred energy storage rack.

In some embodiments a machine-readable data storage includes instructions, that upon execution by a computer or microcontroller cause the computer or microcontroller to perform at least one step of a preferred method.

In some embodiments a machine-readable data storage includes instructions, that upon synthesizing in a programmable circuit chip, configure the circuit chip to perform at least one step of a preferred method.

Advantageous effects of the invention are described in more detail below. It should be noted that not all advantages must be present at the same time or to the same degree.

The idea presented herein has basically three parts. One part involves abnormal cell detection based on the balancing-on-time (BOT), which is the percentage of the total on-time/active time of the cell that is used for balancing. For example, if the storage cell is active for an active time Tₒₙ and there was a balancing time of t_{bal} of balancing the BOT is defined as t_{bal}/Tₒₙ. It is generally assumed that the BOT is associated with leakage current. It should be noted that the BOT can also be influenced by other factors that are not necessarily known, however, the leakage current seems to be more important than those.

Another part involves identifying the voltage balancing requirement for abnormal cells.

Still another part involves “dropping” the abnormal cells, which in this disclosure designates dropping of the operational voltage of the abnormal cells by keeping those cells at a lower voltage than the rest of the cells, while simultaneously keeping the entire system voltage the same, i.e., allowing a voltage offset for dropping those cells.

The main reason for the imbalance between the cell voltages in the ultracapacitors is leakage current difference between the different cells. In this rack level (cell to cell) balancing method, the cells with the highest voltage are preferably balanced by the balancing circuit before the cells with lower voltages.

In a system where imbalance in the rack is within the allowed limit the main goal of the balancing method is preferably keeping the imbalance within the allowed limit. In this case the balancing circuit can be used to equalize the leakage rates between the cells by discharging the cells with lower leakage rate. It can be said that the whole system will follow the cell with the highest leakage current.

In a balanced system, cells with lower leakage current have settled at a higher voltage than cells with higher leakage current. This means that cell leakage current can be characterized by using BOT (defined as percentage of a defined period that the balancing is on/active), where lower leakage current cells have higher BOT than higher leakage current cells. As leakage current steady-state value is voltage dependent, allowing a high leakage cell to have higher imbalance (difference to module maximum cell voltage) can reduce the BOT in the system.

Abnormal cell detection means detecting the cells that have a high leakage current. This detection is based on the BOT difference between individual cells in a module or system. It is assumed that a cell with high leakage current (abnormal cell) has the lowest voltage, when in a balanced state, and the rest of the cells (normal cells) are balanced ahead of it. This means that BOT indicates that the cell has a normal leakage current characteristic. Low or zero BOT means that this cell is rarely balanced and therefore it is assumed to have a higher leakage current compared other cells. Based on this, the BOT can be considered to represent the average leakage current characteristics of the cells. Using BOT difference within the module/system, individual cell BOTs and a predetermined limit for BOT, it is possible to find the abnormal cells.

Cell dropping, as it is called herein, is a functionality of the more general cell balancing methodology. One such cell balancing methodology is a weighted balancing algorithm. Cell dropping allows abnormal cells to have lower voltage than the rest of the cells in order allow a decrease of the BOT. The BOT can be reduced in this case due to the cell leakage current depending on the respective cell voltage. Allowing abnormal cells to operate at decreased voltage therefore allows decreasing the leakage current characteristics difference in the module. This function can be incorporated into the weighted balancing algorithm with system level balancing support functionality.

The approaches behind the cell dropping are: excluding the abnormal cells from rack level balancing, having additional allowed imbalance for abnormal cells, and having separate check on module level to keep the abnormal cells in allowed imbalance window. The exclusion of abnormal cells is not done physically, and the cells retain their energy storage functionality although at a lower voltage.

If an abnormal cell is detected in a module or the system, then that cell is excluded from the maximum and minimum voltage calculation. It should be noted that the cell is not electrically bypassed or disconnected. Additionally, cell voltages in the module where abnormal cells are detected are modified by distributing the decrease in abnormal cell voltages equally between the normal cells.

This can be illustrated by an example, where there are two modules connected in parallel (connected modules have the same terminal voltage due to their electrical connections) and their voltage is, e.g., 90 V before cell dropping and kept at 90 V after cell dropping.

For simplicity it can be assumed that there are no phenomena that cause the cell voltage to change without external help. An abnormal cell can be allowed to drop to a cell voltage of 1.1 V (discharging only this cell while holding voltage at 90 V), which means that each normal cell voltage increases by 0.04 V in the module.

This can be more than the allowed imbalance at that voltage, e.g. 0.03 V. Thus, the balancing algorithm may try to decrease the voltages of normal cells. This, however, would cause the abnormal cell voltage to rise again as the amount discharged from normal cells is charged into the abnormal cell. In this case the 0.04 V are instead subtracted from each cell to allow weighted balancing to operate correctly.

### BRIEF DESCRIPTION OF THE DRAWINGS

Embodiments of the invention are described in more detail with reference to the accompanying schematic drawings that are listed below

FIG. 1 depicts an embodiment of an energy storage system;

FIG. 2 depicts an embodiment of an energy storage module;

FIG. 3 depicts an embodiment of a method for abnormal cell detection;

FIG. 4 depicts an embodiment of a preparatory part of a balancing method; and

FIG. 5 depicts an embodiment of a main part of the balancing method.

### DETAILED DESCRIPTION OF THE PREFERRED EMBODIMENTS

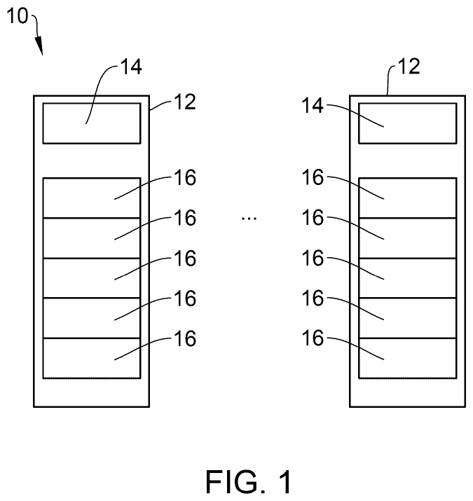

Referring to FIG. 1, an embodiment of an energy storage system 10 is schematically depicted. The energy storage system 10 may be used for grid stabilization, in particular for mitigating the effects of power sags or power disruptions, or for providing peak loads during ramp-up of power intensive machinery or equipment.

The energy storage system 10 may include one or more energy storage racks 12. The energy storage racks 12 that are suitably connected according to the application. The energy storage racks 12 are connected in parallel or in series depending on the application.

Each energy storage rack 12 includes a rack controller 14 and a plurality of energy storage modules 16. The rack controller 14 is configured to control the energy storage modules 16 that are installed in the respective energy storage rack 12. A plurality of rack controllers 14 may operationally form a system controller by communicating with each other. It is also possible for the energy storage system 10 to include a separate system controller (not shown) that communicates with and controls the energy storage racks 12 via the rack controllers 14.

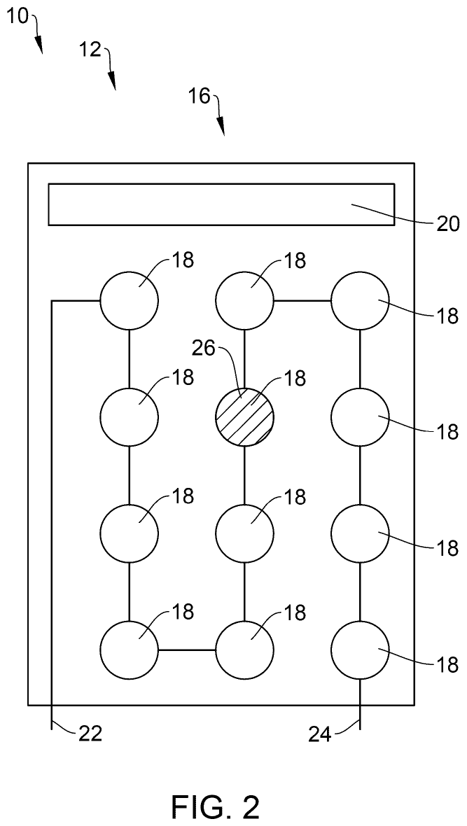

Referring to FIG. 2 the energy storage module 16 is described in more detail. The energy storage module 16 comprises a plurality of energy storage cells 18 and a module controller 20. The energy storage cells 18 are electrically connected in series. A first and second terminal 22, 24 are formed on the energy storage module 16, which allow electrical connection to other energy storage modules 16, preferably of the same energy storage rack 12.

The module controller 20 is configured to control general operation of the energy storage module 16, in particular charging and discharging of the energy storage cells 18. Furthermore, the module controller 20 is operatively coupled to each individual cell to allow controlling a cell voltage V_{cell} of each individual energy storage cell 18. In particular the module controller 20 allows decreasing of the cell voltage V_{cell} during balancing, preferably by discharging the respective energy storage cell 18 using a balancing circuit. In its simplest form the balancing circuit involves a switch, e.g., a transistor, and a balancing resistor.

Each module controller 20 may be operatively coupled to the rack controller 14. In some embodiments, two or more module controllers 20 may collectively form the rack controller 14 without a separate physical component present. It is also possible, that each module controller 20 is integrated into the rack controller 14 as a physical and/or software component thereof.

The rack controller 14, the system controller, and the module controller 20, as the case may be, may be collectively referred to as a storage management system.

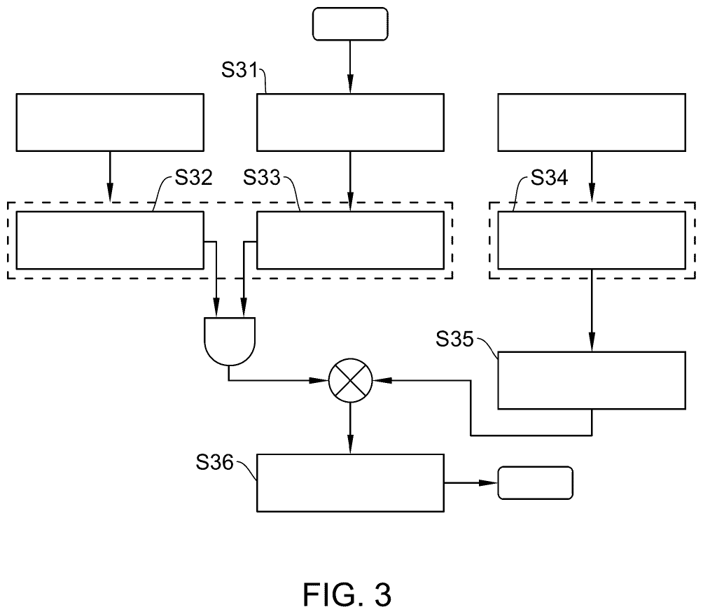

Referring to FIG. 2 and FIG. 3, a method for detecting an abnormal cell 26 is described in more detail. The method is performed in detection periods that can be numbered with n=1, 2, . . . Each detection period preferably lasts for a detection period time t_{det}. The detection period time t_{det} can be predetermined or result from the amount of time needed for the storage management system to execute the respective detection period. In other words, the length of the detection period time t_{det, m} for detection test period m can be different from the detection period time t_{det, n} for the detection period n.

In a data gathering step S31, the storage management system gathers cell data of each energy storage cell 18. The cell data include information that is indicative of a cell leakage level and may also include further information. The cell data include, but are not limited to, the cell balancing-on-time t_{BOT, i}, where i designates the i-th cell. The cell data may further include any of a leakage level limit, a cell initial value, a cell voltage difference, and a cell voltage difference threshold limit.

In first validation step S32 the storage management system determines the maximum BOT t_{BOT, max} and the minimum BOT t_{BOT, min} based on the cell BOTs t_{BOT, i}. If the storage management system determines that a difference between the maximum BOT t_{BOT, max} and the minimum BOT t_{BOT, min} is greater than or equal to a predetermined threshold BOT, e.g. 30%, the storage management system sets a first detection condition to “true”.

In a second validation step S33, the storage management system also calculates an imbalance change ΔΔV=ΔVₙ−ΔVₙ₋₁ among the energy storage cells 18 between the current detection period n and the previous detection period n−1. ΔVₙ, ΔVₙ₋₁ are the average imbalance during the respective detection periods n and n−1. If the imbalance change ΔΔV is smaller than a predetermined voltage imbalance threshold, the storage management system sets a second detection condition to “true”.

In a first identification step S34, the storage management system determines an individual cell leakage level for each energy storage cell 18. The individual cell leakage level is determined based on the respective energy storage cell's 18 balancing-on-time t_{BOT, i} and the difference between the maximum balancing-on-time t_{BOT, max} and the minimum balancing-on-time t_{BOT, min}, i.e., (t_{BOT, max}−t_{BOT, min})−t_{BOT, i}.

In a second identification step S35, the result of the first identification step S34 is compared with a predetermined abnormality threshold. If the result of the first identification step S34 is greater than or equal to the predetermined abnormality threshold, the respective energy storage cell 18 is identified as the abnormal cell 26.

In a storage step S36, the abnormal cell 26 is stored as behaving abnormal within the current detection time period t_{det}, if, and preferably only if, in addition to the result of the second identification step S35, both the first and second validation steps S32 and S33 result in the first and second detection conditions being “true”.

After the storage step S36, the current detection period n is completed and the next detection period n+1 can be started by the storage management system, as the case may be, after some delay or directly thereafter. It is also possible for the storage management system to carry out an iteration of another method, before carrying out the next detection period n+1 of the detection method.

With this method the abnormal cell 26 is identified based on the cell BOT t_{BOT, i}. It should be noted that while the method was described in reference to a single energy storage module 16, the method disclosed herein is also applicable for energy storage racks 12 or the energy storage system 10 as a whole.

In the case of the energy storage racks 12 or the energy storage system 10, the energy storage cells 18 can be uniquely indexed and the whole configuration is preferably treated as a single entity, i.e., the method does not distinguish between the energy storage cells 18 being in different energy storage modules 16 or energy storage racks 12.

If only a single energy storage module 16 is involved, the storage management system is preferably formed by the module controller 20.

If multiple energy storage modules 16 and a single energy storage rack 12 are involved, the storage management system may be formed collectively by the module controllers 20 of the energy storage modules 16, or optionally by the rack controller 14.

If multiple energy storage racks 12 are involved, the storage management system may be collectively formed by the rack controllers 14 and/or the module controllers 20. It is also possible that a separate system controller forms the storage management system that controls the entire energy storage system 10.

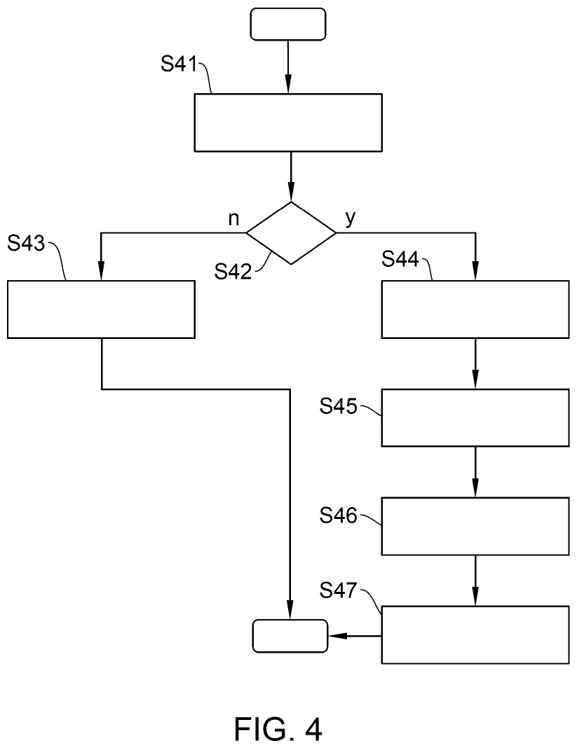

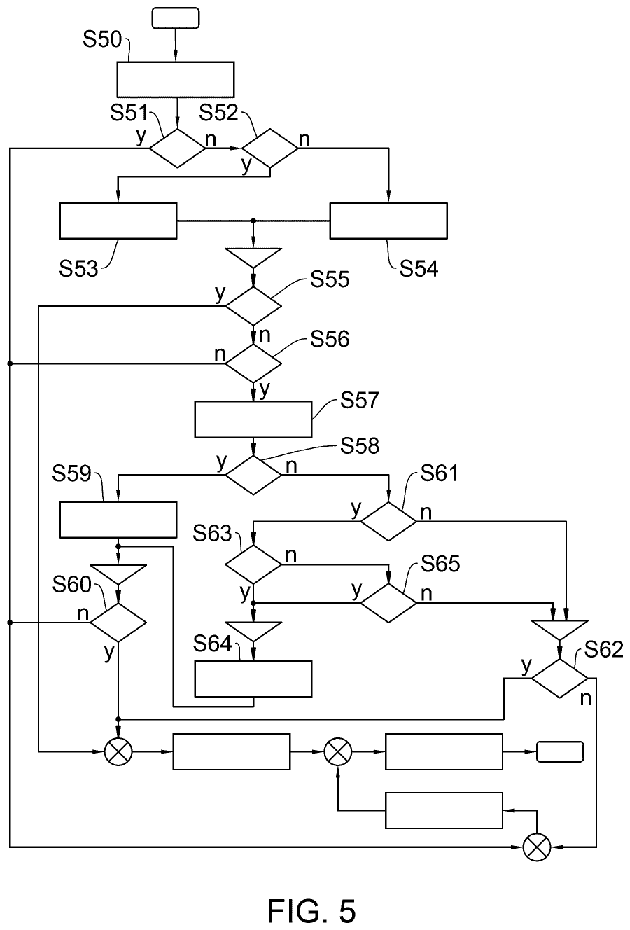

Referring to FIG. 4 and FIG. 5 an embodiment of a balancing method according to the invention is described.

FIG. 4 illustrates a preparatory part of the balancing method that determines certain useful inputs to the main part of the balancing method of FIG. 5.

In a data gathering step S41, the storage management system gathers cell data of each energy storage cell 18. The cell data includes information that is indicative of a cell leakage level. The cell data includes, but are not limited to the abnormal cells 24, cell voltage Vᵢ, maximum allowed imbalance for abnormal cells 24, maximum cell voltage increase for normal cells 18. In some embodiments the method for detecting abnormal cells 24 is carried out before. In some embodiments the method for detecting abnormal cells 24 can be carried out during this data gathering step S41.

In an abnormal cell detection checking step S42 it is checked, whether at least one abnormal cell 26 was detected by a suitable method, such as the previously described one. It is also possible to use a well-known abnormal cell detection method, as long as it is able to identify individual energy storage cells 18 as behaving abnormal.

If no abnormal cell 26 is detected, the method proceeds with an unmodified initiation step S43 in which the balancing method is initiated with neutral parameters, e.g., by calculating maximum and a minimum normal cell voltage V_{min, norm}, V_{max, norm} for all energy storage cells.

If an abnormal cell 26 is detected, the method proceeds with a voltage determination step S44. In this step, the storage management system determines a normal cell voltage increase V_{HLCD Mdy} based on the maximum cell voltage Vₘₐₓ of all the energy storage cells 18 and the individual cell voltages Vᵢ according to:

$${V}_{HLCD Mdy} = {V}_{max} - \frac{( n - k ) \cdot {V}_{max} + ( {\sum }_{i = 1}^{k} {V}_{i} )}{n} ;$$

where n is the total number of energy storage cells 18 and k is the total number of abnormal cells 26. The normal cell voltage increase V_{HLCD Mdy} is indicative of the amount that the cell voltage of each normal energy storage cell 18 increases due to allowing the abnormal cells 26 to drop, i.e., decrease their respective voltage Vᵢ.

Furthermore, the storage management system determines an abnormal delta voltage V_{HLCD abnormal delta} based on a predetermined limit V_{HLCD limit}, the average cell voltage V_{avg}, and the individual cell voltages Vᵢ according to:

$${V}_{HLCD abnormal delta} = {V}_{HLCD limit} \cdot ( n - k ) - ( k \cdot {V}_{avg} - {\sum }_{i = 1}^{k} {V}_{i} ) ;$$

where n is the total number of energy storage cells 18 and k is the total number of abnormal cells 24. The abnormal delta voltage V_{HLCD abnormal delta} is indicative of a difference between the total decrease of abnormal cell voltages, and the allowed limit of total increase of normal cell voltages.

In a maximum imbalance step S45, the storage management system determines the maximum allowed imbalance for abnormal cells 24 based on a predetermined limit, e.g., 1 V, or calculated based on cell voltage and leakage current characteristics.

In an exclusion step S46, the storage management system excludes the abnormal cells 24 from determining a maximum and a minimum normal cell voltage V_{min, norm}, V_{max, norm} of all energy storage cells 18. In other words, the storage management system determines the maximum and minimum normal cell voltage V_{min, norm}, V_{max, norm} of all normal energy storage cells 18. It should be noted that the storage management system only excludes the abnormal cells 24 for the purposes of calculation only. The abnormal cells 24 are thus not physically disconnected from the circuit or bypassed, but remain connected to the normal energy storage cells 18.

In a modified calculation step S47, the storage management system determines the input minimum and maximum algorithm voltages V_{algo, min}, V_{algo, max} as input parameters for the balancing method by subtracting the normal cells voltage increase due to allowing cells to drop V_{HLCD Mdy} from the minimum and maximum normal cell voltage V_{min, norm}, V_{max, norm}. The minimum and maximum algorithm voltages V_{algo, min}, V_{algo, max} are closely related to and preferably represent the minimum and maximum voltage as if there was no cell drop. After this step, the storage management system may carry out the main part of the balancing method.

Referring to FIG. 5, the main part of the balancing method is described in more detail.

In a data gathering step S50, the storage management system gathers cell data of each energy storage cell 18 and rack data of each energy storage rack 12, if applicable. The cell data include information that is indicative of a cell BOT. The cell data and/or rack data may include, but are not limited to, a balancing suspend flag, cell voltages Vᵢ, minimum and maximum algorithm voltages V_{algo, min}, V_{algo, max} as previously determined, module minimum and maximum voltages V_{mod, min}, V_{mod, max}, actual rack voltage V_{rack, j}, where j designates the energy storage rack 12, reference rack voltage V_{rack, ref}, nominal module voltage V_{mod, nom}, number of cells n, allowed rack offset, normal cells voltage increase due to allowing cells to drop V_{HLCD Mdy}, abnormal delta voltage V_{HLCD abnormal delta}, and/or maximum allowed imbalance for abnormal cells.

In a first branching step S51, the storage management system determines, whether the balance suspend flag is set. If the balance suspend flag is set, the storage management system main part of the balancing method is not performed and the next iteration of the preparatory part and/or the abnormal cell detection can be started.

If the balancing suspend flag is not set, the storage management system proceeds to a second branching step S52. In this step S52, the storage management system checks, whether the reference rack voltage V_{rack, ref} is smaller than a predetermined balancing minimum limit. The balancing minimum limit basically is the threshold below which balancing is not possible due to a lack of balancing capacity. The balancing minimum limit can be determined experimentally.

If the storage management system determines that the reference rack voltage V_{rack, ref} is smaller than the balancing minimum limit, then all system balancing values, i.e., difference between the rack voltage V_{rack, j} and the rack reference voltage V_{rack, ref}, and system balancing need for each energy storage cell 18 are set to 0, in a zeroing step S53.

If the storage management system determines that the reference rack voltage V_{rack, ref} is greater than or equal to the balancing minimum limit, the storage management system determines a difference between the rack voltage V_{rack, j} and the rack reference voltage V_{rack, ref} in a voltage determination step S54.

Furthermore, the storage management system determines the system balancing needs for each energy storage cell 18 individually, i.e. how much the respective cell voltage Vᵢ should be changed.

After steps S53 and S54 the storage management system proceeds to a third branching step S55. In this step, the storage management system checks, whether the cell voltage Vᵢ minus the normal cell voltage increase V_{HLCD Mdy} exceeds the maximum balancing limit.

If so, the balancing flag is set to “true” and balancing is performed by the storage management system.

If not, the storage management system proceeds to a fourth branching step S56. In this step, the storage management system checks, whether the cell voltage Vᵢ minus the normal cell voltage increase V_{HLCD Mdy} exceeds the minimum balancing limit.

If not, the storage management system performs no balancing and the next iteration of the preparatory part and/or the abnormal cell detection can be started.

If the condition is met, the storage management system proceeds to calculate the allowed imbalance in an allowed imbalance determination step S57.

The storage management system proceeds to a fifth branch step S58, in which it checks, whether the difference of the minimum and maximum algorithm voltages V_{algo, min}, V_{algo, max} is greater than the allowed imbalance.

If so, each cell balancing coefficient C_{cell bal} for rack level balancing is determined for each individual energy storage cell 18 in a first cell balancing determination step S59 as follows:

$${C}_{cell bal} = \frac{{V}_{i} - {V}_{HLCD Mdy} + Δ {V}_{sys bal} - {V}_{min algo}}{{V}_{max algo} - {V}_{min algo}} ;$$

where Vᵢ is the cell voltage of the i-th cell, V_{HLCD Mdy} is the normal cell voltage increase, ΔV_{sys bal} is the system balancing need for individual cell, V_{min algo} is the minimum algorithm voltage, and V_{max algo} is the maximum algorithm voltage.

After the step S59, the storage management system proceeds to a sixth branching step S60. In this step, the storage management system checks, whether the cell balancing coefficient C_{cell bal} exceeds a coefficient limit threshold.

If so, the storage management system sets the balancing flag to “true” and balances the respective energy storage cells 18 whose balancing coefficients exceeded the coefficient limit threshold.

If not, the storage management system performs no balancing and the next iteration of the preparatory part and/or the abnormal cell detection can be started.

If in the fifth branch step S58, the storage management system determines that the difference of the minimum and maximum algorithm voltages V_{algo, min}, V_{algo, max} is smaller than or equal to the allowed imbalance determined in step S57 the storage management system proceeds to a seventh branching step S61.

In this step S61, the storage management system checks, whether the maximum allowed imbalance for abnormal cells exceeds 0.

If not, the storage management system checks in an eighth branching step S62, whether a difference between the rack voltage V_{rack} and the rack reference voltage V_{rack, ref} exceeds the allowed rack imbalance.

If not, the balancing flag is set to “false” and the next iteration of the preparatory part and/or the abnormal cell detection can be started.

If the condition is met, the balancing flag is set to “true” and balancing is performed by the storage management system.

If in step S61, the storage management system determines that the maximum allowed imbalance for abnormal cells exceeds 0, a ninth branching step S63 is performed.

In this step S63, the storage management system checks, whether the difference of the minimum and maximum cell voltage V_{min, mod}, V_{max, mod} in each energy storage cell 18 where at least one abnormal cell 26 was detected is larger than the allowed imbalance for abnormal cells.

If so, the storage management system calculates cell balancing coefficients C_{cell bal} in a second cell balancing determination step S64 according to:

$${C}_{cell bal} = \frac{{V}_{i} + Δ {V}_{sys bal} - {V}_{min mod}}{{V}_{max mod} - {V}_{min mod}} ;$$

where Vᵢ is the cell voltage of the i-th cell, ΔV_{sys bal} is the system balancing need for individual cell, V_{min mod} is the module minimum voltage, and V_{max mod} is the maximum module voltage.

The method then proceeds to the sixth branching step S60.

If in step S63, the condition is not met, a tenth branching step S65 checks, whether the abnormal delta voltage V_{HLCD abnormal delta} is smaller than 0.

If so, the method proceeds to the second cell balancing determination step S64.

If not, the method proceeds to the eighth branching step S62.

The systems and devices described herein may include a controller or a computing device comprising a processing unit and a memory which has stored therein computer-executable instructions for implementing the processes described herein. The processing unit may comprise any suitable devices configured to cause a series of steps to be performed so as to implement the method such that instructions, when executed by the computing device or other programmable apparatus, may cause the functions/acts/steps specified in the methods described herein to be executed. The processing unit may comprise, for example, any type of general-purpose microprocessor or microcontroller, a digital signal processing (DSP) processor, a central processing unit (CPU), an integrated circuit, a field programmable gate array (FPGA), a reconfigurable processor, other suitably programmed or programmable logic circuits, or any combination thereof.

The memory may be any suitable known or other machine-readable storage medium. The memory may comprise non-transitory computer readable storage medium such as, for example, but not limited to, an electronic, magnetic, optical, electromagnetic, infrared, or semiconductor system, apparatus, or device, or any suitable combination of the foregoing. The memory may include a suitable combination of any type of computer memory that is located either internally or externally to the device such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like. The memory may comprise any storage means (e.g., devices) suitable for retrievably storing the computer-executable instructions executable by processing unit.

The methods and systems described herein may be implemented in a high-level procedural or object-oriented programming or scripting language, or a combination thereof, to communicate with or assist in the operation of the controller or computing device. Alternatively, the methods and systems described herein may be implemented in assembly or machine language. The language may be a compiled or interpreted language. Program code for implementing the methods and systems described herein may be stored on the storage media or the device, for example a ROM, a magnetic disk, an optical disc, a flash drive, or any other suitable storage media or device. The program code may be readable by a general or special-purpose programmable computer for configuring and operating the computer when the storage media or device is read by the computer to perform the procedures described herein.

Computer-executable instructions may be in many forms, including modules, executed by one or more computers or other devices. Generally, modules include routines, programs, objects, components, data structures, etc., that perform particular tasks or implement particular abstract data types. Typically, the functionality of the modules may be combined or distributed as desired in various embodiments.

It will be appreciated that the systems and devices and components thereof may utilize communication through any of various network protocols such as TCP/IP, Ethernet, FTP, HTTP and the like, and/or through various wireless communication technologies such as GSM, CDMA, Wi-Fi, and WiMAX, is and the various computing devices described herein may be configured to communicate using any of these network protocols or technologies.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

### LIST OF REFERENCE SIGNS

10 energy storage system
12 energy storage rack
14 rack controller
16 energy storage module
18 energy storage cells
20 module controller
22 first terminal
24 second terminal
26 abnormal cell
S31 data gathering step
S32 first validation step
S33 second validation step
S34 first identification step
S35 second identification step
S36 storage step
S41 data gathering step
S42 abnormal cell detection checking step
S43 unmodified initiation step
S44 voltage determination step
S45 maximum imbalance step
S46 exclusion step
S47 modified calculation step
S50 data gathering step
S51 first branching step
S52 second branching step
S53 zeroing step
S54 voltage determination step
S55 third branching step
S56 fourth branching step
S57 allowed imbalance determination step
S58 fifth branch step
S59 first cell balancing determination step
S60 sixth branching step
S61 seventh branching step
S62 eight branching step
S63 ninth branching step
S64 second cell balancing determination step
S65 tenth branching step

Claimed is:

1. A method for detecting an abnormal cell in an energy storage system, the energy storage system comprising a plurality of energy storage cells connected in series and operatively coupled to a storage management system, the storage management system performing the steps of:
a) for each energy storage cell, obtaining cell data indicative of a cell leakage current level of a respective energy storage cell, the cell data at least including balancing-on-time;
b) for each energy storage cell, determining a cell leakage level based on the balancing-on-time; and
c) for each energy storage cell, determining a energy storage cell to be an abnormal cell, when a result of step b) exceeds a predetermined threshold and, optionally, meets at least one condition during a current detection period, and storing the energy storage cell as being an abnormal cell for the current detection period.

2. The method according to claim 1, wherein step b) includes:
b1) determining an imbalance change among the energy storage cells between the current detection period and a directly preceding detection period, wherein a first condition is met, when the imbalance change is smaller than a predetermined threshold; or
b2) determining a difference between a minimum BOT and a maximum BOT among the energy storage cells, wherein a second condition is met, when this difference is greater or equal to a predetermined threshold; or
both.

3. The method according to claim 2, wherein step c) includes:
c1) the energy storage cell is determined to be an abnormal cell, when the result of step b) exceeds the predetermined threshold and each condition is met.

4. The method according to claim 1, wherein steps a) to c) are carried out in a loop.

5. A method for balancing an energy storage system, the energy storage system comprising at least one energy storage module, each energy storage module having a plurality of energy storage cells, the method comprising a storage management system performing the steps of:
a) determining a normal cell voltage increase for normal energy storage cells due to allowing abnormal cells to drop, and determining a maximum imbalance for abnormal cells;
b) determining a minimum cell voltage and a maximum cell voltage of all energy storage cells excluding the abnormal cells; and,
c) determining a minimum algorithm voltage and a maximum algorithm voltage for further processing in a balancing method by subtracting the normal cell voltage increase for normal energy storage cells due to allowing abnormal cells to drop from the minimum cell voltage and maximum cell voltage obtained in step b).

6. A method for balancing an energy storage system, the energy storage system comprising at least one energy storage module, each energy storage module having a plurality of energy storage cells, the method comprising a storage management system to perform the steps of:
a) detecting the presence of at least one abnormal cell;
b) determining a normal cell voltage increase due to allowing each abnormal cell to drop in voltage;
c) for each energy storage cell, setting the respective energy storage cell to a balance-on-state or a balance-off-state depending on the result of step b), wherein in the balance-on-state an operating voltage of the energy storage cell is decreased.

7. The method according to claim 6, wherein in step a) a presence of each abnormal cell is detected by a method comprising:
a1) for each energy storage cell, obtaining cell data indicative of a cell leakage current level of a respective energy storage cell, the cell data at least including balancing-on-time;
b1) for each energy storage cell, determining a cell leakage level based on the balancing-on-time; and
c1) for each energy storage cell, determining a energy storage cell to be an abnormal cell, when a result of step b1) exceeds a predetermined threshold and, optionally, meets at least one condition during a current detection period, and storing the energy storage cell as being an abnormal cell for the current detection period.

8. The method according to claim 6, wherein step b) comprises:
A1) determining a normal cell voltage increase for normal energy storage cells due to allowing abnormal cells to drop, and determining a maximum imbalance for abnormal cells;
b1) determining a minimum cell voltage and a maximum cell voltage of all energy storage cells excluding the abnormal cells; and,
c1) determining a minimum algorithm voltage and a maximum algorithm voltage for further processing in a balancing method by subtracting the normal cell voltage increase for normal energy storage cells due to allowing abnormal cells to drop from the minimum cell voltage and maximum cell voltage obtained in step b1).

9. The method according to claim 6, wherein step b) includes determining a cell balancing coefficient, and step c) includes setting the respective energy storage cell to the balancing-on-state, when the cell balancing coefficient exceeds a predetermined threshold, and setting the respective energy storage cell to the balancing-off-state otherwise.

10. The method according to claim 6, wherein step b) includes determining a maximum allowed imbalance for abnormal cells and determining an abnormal delta voltage, wherein the abnormal delta voltage is indicative of a difference between a total decrease of abnormal cell voltages, and an allowed limit of a total increase of normal cell voltages, and
wherein step c) includes setting the respective energy storage cell to the balancing-on-state, when the maximum allowed imbalance is smaller than or equal to zero or when the abnormal delta voltage is greater than or equal to zero, and to the balancing-off-state otherwise.

11. A storage management system configured to perform the method of claim 1.

12. An energy storage module comprising:
a plurality of energy storage cells and
the storage management system according to claim 11, wherein the storage management system is configured as a module controller.

13. An energy storage rack comprising:
a plurality of energy storage modules, each including a plurality of energy storage cells, and
the storage management system according to claim 11.

14. An energy storage system comprising:
at least one energy storage rack according to claim 13.

15. A non-transitory computer readable media storing instructions, that upon execution by a computer or microcontroller cause the computer or microcontroller to perform the method of claim 1.
